(19) United States
(12) Patent Application Publication
(10) Pub. No.: US 2021/0304964 A1
(43) Pub. Date: Sep. 30, 2021

(54) CAPACITOR

(71) Applicant: Faraday Technology Corp., Hsinchu (TW)

(72) Inventors: Chia-Hui Tien, Hsinchu (TW); Tung-Tse Lin, Hsinchu (TW); Chih-Yuan Hung, Hsinchu (TW); Chih-Shiun Lu, Hsinchu (TW)

(73) Assignee: Faraday Technology Corp., Hsinchu (TW)

(21) Appl. No.: 16/942,710

(22) Filed: Jul. 29, 2020

(30) Foreign Application Priority Data
Mar. 30, 2020 (TW) 109110750

(51) Int. Cl. H01G 4/012; H01G 4/228; H01G 4/33; H01L 49/02

(52) U.S. Cl. CPC H01G 4/012; H01L 28/86; H01G 4/33; H01G 4/228

(57) ABSTRACT

A capacitor includes a solid conductive plate, a first electrode, and a second electrode. The solid conductive plate is disposed above a substrate of a wafer. The solid conductive plate serves as a bottom plate of the capacitor. The first electrode is disposed above the solid conductive plate so that the solid conductive plate is located between the substrate and the first electrode. This first electrode serves as a top plate of the capacitor. The second electrode is disposed above the solid conductive plate, and is disposed beside the first electrode. The second electrode is electrically connected to the solid conductive plate.

### CROSS-REFERENCE TO RELATED APPLICATION

This application claims the priority benefit of Taiwan application serial no. 109110750, filed on Mar. 30, 2020. The entirety of the above-mentioned patent application is hereby incorporated by reference herein and made a part of this specification.

### BACKGROUND

### Field of the Disclosure

The disclosure relates to an integrated circuit, and particularly to a capacitor.

### Description of Related Art

Capacitors are commonly used in various integrated circuits. Capacitors can be implemented with various structures. For example, a capacitor structure may include an interdigitated finger structure to produce fringing capacitance. In general, the capacitor structure is arranged above the substrate of the wafer, and the substrate is grounded. There is an undesirable parasitic capacitor between the top plate of the capacitor and the substrate. This parasitic capacitor will affect (reduce) the effective capacitance of the capacitor.

It should be noted that the content of the section “related art” is used to help understand the present disclosure. Part of the content (or the entire content) disclosed in the section “related art” may not be the conventional technology known to those with ordinary knowledge in the technical field. The content disclosed in the section “related art” does not mean that the content has been known by those with ordinary knowledge in the technical field before the application of the present disclosure.

### SUMMARY OF THE DISCLOSURE

The disclosure provides a capacitor, so that the parasitic capacitor between the top plate and the substrate of the capacitor can be as small as possible.

The capacitor of the disclosure includes a solid conductive plate, a first electrode, and a second electrode. The solid conductive plate is arranged above the substrate of the wafer. This solid conductive plate serves as the bottom plate of the capacitor. The first electrode is arranged above the solid conductive plate so that the solid conductive plate is located between the substrate and the first electrode. The first electrode serves as the top plate of the capacitor. The second electrode is arranged above the solid conductive plate and beside the first electrode. The second electrode is electrically connected to the solid conductive plate.

Based on the above, the capacitor in the embodiment of the disclosure uses the bottom plate (solid conductive plate) as a shielding layer. The solid conductive plate can effectively reduce the parasitic capacitor between the top plate of the capacitor and the substrate of the wafer.

In order to make the above-mentioned features and advantages of the present invention more obvious and understandable, the embodiments are specifically described below and described in detail in conjunction with the accompanying drawings.

### BRIEF DESCRIPTION OF THE DRAWINGS

FIG. 1 is an exploded schematic view illustrating a layout structure of a capacitor according to an embodiment of the disclosure.

FIG. 2 is a schematic cross-sectional view illustrating a layout structure of a capacitor according to an embodiment of the disclosure.

FIG. 3 is an exploded schematic view illustrating a layout structure of a capacitor according to another embodiment of the disclosure.

FIG. 4 is a schematic cross-sectional view illustrating a layout structure of a capacitor according to still another embodiment of the disclosure.

FIG. 5 is a schematic top view illustrating a layout structure of a capacitor according to yet another embodiment of the disclosure.

FIG. 6 is a schematic cross-sectional view illustrating a layout structure of a capacitor according to still another embodiment of the disclosure.

FIG. 7 is a schematic top view showing a layout structure of a capacitor according to yet another embodiment of the disclosure.

### DESCRIPTION OF EMBODIMENTS

The term “coupling/coupled” used in this specification (including claims) may refer to any direct or indirect connection means. For example, “a first device is coupled to a second device” should be interpreted as “the first device is directly connected to the second device” or “the first device is indirectly connected to the second device through other devices or connection means.” Terms such as “first” and “second” mentioned in the specification or the claims are only for naming the elements or distinguishing different embodiments or scopes and are not intended to limit the upper limit or the lower limit of the number of the elements or to limit the order the elements. Moreover, wherever appropriate in the drawings and embodiments, elements/components/steps with the same reference numerals represent the same or similar parts. Elements/components/steps with the same reference numerals or names in different embodiments may be cross-referenced.

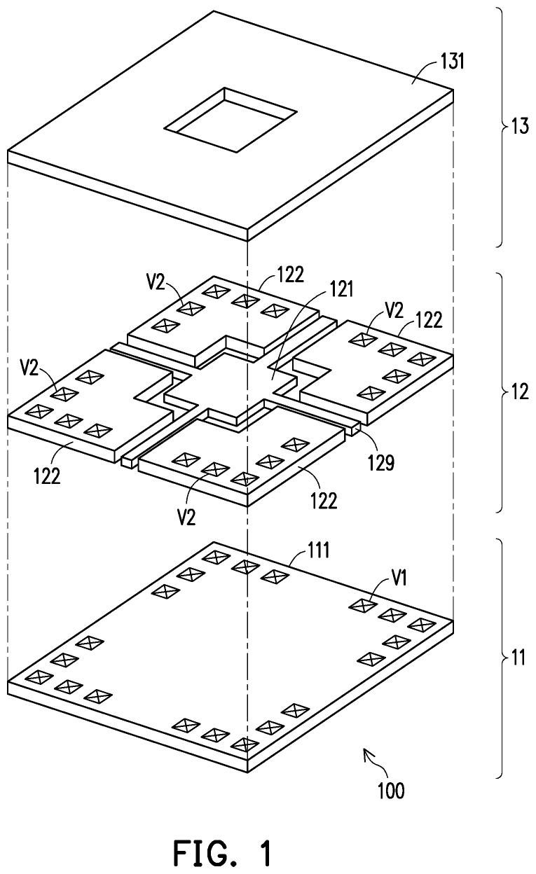

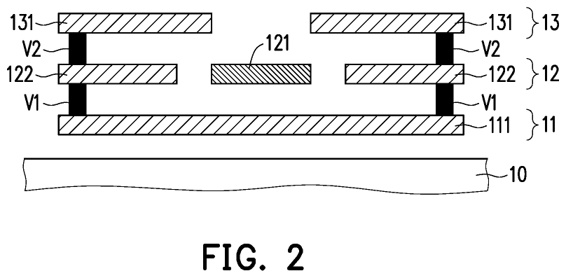

FIG. 1 is an exploded schematic view illustrating a layout structure of a capacitor 100 according to an embodiment of the disclosure. FIG. 2 is a schematic cross-sectional view illustrating a layout structure of a capacitor 100 according to an embodiment of the disclosure. FIG. 1 and FIG. 2 illustrate a first conductive layer 11, a second conductive layer 12 and a third conductive layer 13. Please refer to FIG. 1 and FIG. 2. The first conductive layer 11, the second conductive layer 12, and the third conductive layer 13 may be any conductive layer (such as a metal layer, a polysilicon layer, or other conductive layers) above a substrate 10 of a wafer. The third conductive layer 13 is disposed above the substrate 10, and the first conductive layer 11 and the second conductive layer 12 are disposed between the substrate 10 and the third conductive layer 13. An insulating layer (not shown) is disposed between the first conductive layer 11 and the second conductive layer 12, and an insulating layer (not shown) is also disposed between the second conductive layer 12 and the third conductive layer 13.

The capacitor 100 shown in FIG. 1 includes a solid conductive plate 111, a first electrode 121, and a second electrode 122. Please refer to FIG. 1 and FIG. 2. The solid conductive plate 111 may be a conductive plate without openings. The solid conductive plate 111 is arranged above the substrate 10 of the wafer. For example, the solid conductive plate 111 may be disposed at the first conductive layer 11. The material of the solid conductive plate 111 can be any conductive material, such as metal, polysilicon, or other conductive materials. The solid conductive plate 111 can serve as a bottom plate (i.e., a lower electrode plate) of the capacitor 100.

The first electrode 121 is arranged above the solid conductive plate 111, so that the solid conductive plate 111 is located between the substrate 10 of the wafer and the first electrode 121. For example, the first electrode 121 may be disposed at the second conductive layer 12. The material of the first electrode 121 may be any conductive material, such as metal, polysilicon, or other conductive materials. The first electrode 121 may serve as a top plate (i.e., an upper electrode plate) of the capacitor 100. In the embodiments shown in FIG. 1 and FIG. 2, the geometric shape of the first electrode 121 is rectangular. In any case, other embodiments of the disclosure are not limited thereto. The geometric shape of the first electrode 121 can be determined according to design requirements.

The second electrode 122 is arranged above the solid conductive plate 111. For example, the second electrode 122 may be disposed at the second conductive layer 12. The material of the second electrode 122 may be any conductive material, such as metal, polysilicon, or other conductive materials. The second electrode 122 is arranged beside the first electrode 121. For example, the second electrode 122 may encircle the first electrode 121. The second electrode 122 may be electrically connected to the solid conductive plate 111 through a plurality of via plugs V1. The second electrode 122 has a notch to accommodate a wire 129. The top plate (first electrode 121) of the capacitor 100 can be electrically connected to other circuits/elements (not shown) through the wire 129.

According to design requirements, the capacitor 100 shown in FIG. 1 may further include an upper conductive plate 131. Please refer to FIG. 1 and FIG. 2. The upper conductive plate 131 is disposed above the first electrode 121 and the second electrode 122, so that the first electrode 121 and the second electrode 122 are located between the upper conductive plate 131 and the solid conductive plate 111. For example, the upper conductive plate 131 may be disposed at the third conductive layer 13. The material of the upper conductive plate 131 may be any conductive material, such as metal, polysilicon, or other conductive materials. The upper conductive plate 131 may be electrically connected to the second electrode 122 through a plurality of via plugs V2. Therefore, the upper conductive plate 131 can be electrically connected to the solid conductive plate 111. According to design requirements, the central portion of the upper conductive plate 131 may have at least one opening. The size and/or geometric shape of the at least one opening can be determined according to design requirements. For example, the at least one opening may be a rectangular opening, and the width of the at least one opening may be less than (or equal to) half of the width of the upper conductive plate 131.

The capacitor 100 shown in FIG. 1 and FIG. 2 may use the bottom plate (solid conductive plate 111) as a shielding layer. The solid conductive plate 111 can effectively reduce the parasitic capacitor between the top plate (first electrode 121) of the capacitor 100 and the substrate 10 of the wafer. In the embodiments shown in FIG. 1 and FIG. 2, the geometric shapes of the solid conductive plate 111, the second electrode 122 and the upper conductive plate 131 are rectangular. In any case, other embodiments of the disclosure are not limited thereto. The geometric shape of the solid conductive plate 111, the geometric shape of the second electrode 122, and the geometric shape of the upper conductive plate 131 can be determined according to design requirements.

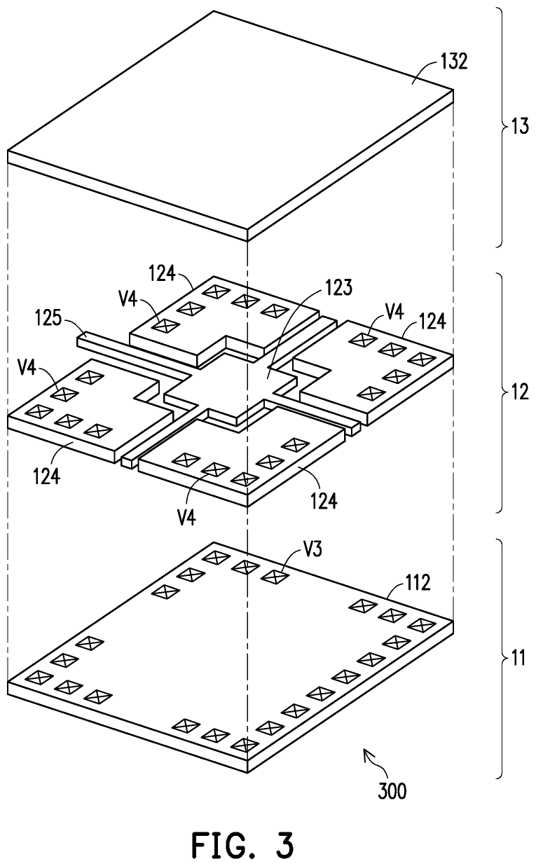

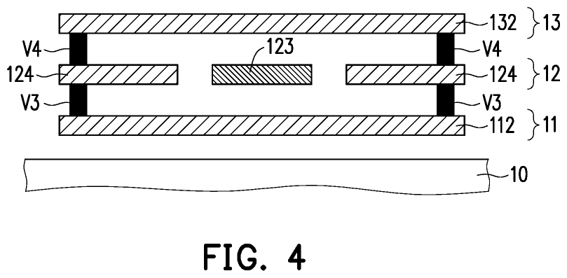

FIG. 3 is an exploded schematic view illustrating a layout structure of a capacitor 300 according to another embodiment of the disclosure. FIG. 4 is a schematic cross-sectional view illustrating a layout structure of a capacitor 300 according to still another embodiment of the disclosure. For the substrate 10, the first conductive layer 11, the second conductive layer 12, and the third conductive layer 13 shown in FIG. 3 and FIG. 4, reference may be made to the related descriptions of FIG. 1 and FIG. 2. Therefore, no repetition is incorporated herein.

Please refer to FIG. 3 and FIG. 4. The capacitor 300 includes a solid conductive plate 112, a first electrode 123, and a second electrode 124. For the capacitor 300, the solid conductive plate 112, the first electrode 123, and the second electrode 124 shown in FIG. 3 and FIG. 4, related descriptions may be derived from the descriptions of the capacitor 100, the solid conductive plate 111, the first electrode 121, and the second electrode 122 shown in FIG. 1 and FIG. 2, and the therefore no repetition is incorporated herein. The second electrode 124 may be electrically connected to the solid conductive plate 112 through a plurality of via plugs V3. The second electrode 124 has a notch to accommodate the wire 125. The top plate (first electrode 123) of the capacitor 300 may be electrically connected to other circuits/elements (not shown) through the wire 125.

According to design requirements, the capacitor 300 may further include an upper conductive plate 132. The upper conductive plate 132 may be electrically connected to the second electrode 124 through a plurality of via plugs V4. Therefore, the upper conductive plate 132 can be electrically connected to the solid conductive plate 112. For the upper conductive plate 132 shown in FIG. 3 and FIG. 4, related descriptions can be derived from descriptions of the upper conductive plate 131 shown in FIG. 1 and FIG. 2. Therefore, no repetition is incorporated herein. As compared with the upper conductive plate 131, the difference lies in that the upper conductive plate 132 is another solid conductive plate (without openings).

In the above embodiments, the geometric shape of the first electrode between the upper conductive plate and the solid conductive plate (the bottom plate of the capacitor) is rectangular. In any case, other embodiments of the disclosure are not limited thereto. The geometric shape of the first electrode and the geometric shape of the second electrode can be determined according to design requirements.

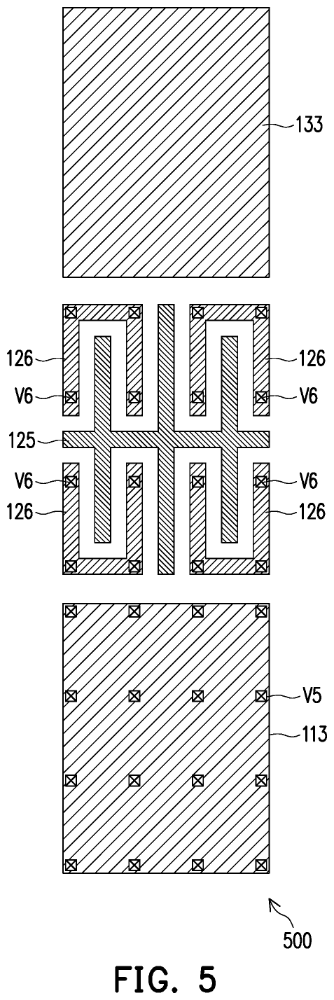

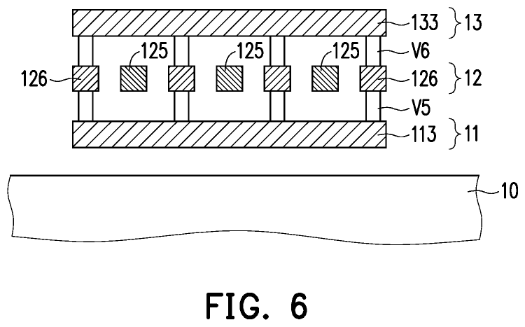

For example, FIG. 5 is a schematic top view illustrating a layout structure of a capacitor 500 according to yet another embodiment of the disclosure. FIG. 6 is a schematic cross-sectional view illustrating a layout structure of a capacitor 500 according to still another embodiment of the disclosure. For the substrate 10, the first conductive layer 11, the second conductive layer 12, and the third conductive layer 13 shown in FIG. 5 and FIG. 6, reference may be made to the related descriptions of FIG. 1 and FIG. 2, so no repetition is incorporated herein.

Please refer to FIG. 5 and FIG. 6. The capacitor 500 includes a solid conductive plate 113, a first electrode 125, and a second electrode 126. For the capacitor 500, the solid conductive plate 113, the first electrode 125, and the second electrode 126 shown in FIG. 5 and FIG. 6, related description may be derived from related description of the capacitor 100, the solid conductive plate 111, the first electrode 121, and the second electrode 122 shown in FIG. 1 and FIG. 2, and (or) from related description of the capacitor 300, the solid conductive plate 112, the first electrode 123, and the second electrode 124 shown in FIG. 3 and FIG. 4.

In the embodiments shown in FIG. 5 and FIG. 6, the second electrode 126 may be electrically connected to the solid conductive plate 113 through a plurality of via plugs V5. Different from the embodiments shown in FIG. 3 and FIG. 4, there is an interdigitated fingers structure between the first electrode 125 and the second electrode 126. The second electrode 126 may encircle the first electrode 125 to reduce the parasitic capacitor between the top plate (first electrode 125) of the capacitor 500 and the substrate 10 of the wafer.

According to design requirements, the capacitor 500 may further include an upper conductive plate 133. The upper conductive plate 133 may be electrically connected to the second electrode 126 through a plurality of via plugs V6. Therefore, the upper conductive plate 133 can be electrically connected to the solid conductive plate 113. For the upper conductive plate 133 shown in FIG. 5 and FIG. 6, related descriptions may be derived from the description of the upper conductive plate 131 shown in FIG. 1 and FIG. 2. Therefore, no repetition is incorporated herein. As compared with the upper conductive plate 131, the difference lies in that the upper conductive plate 133 is another solid conductive plate (without openings).

In the above embodiments, there is a single conductive layer between the upper conductive plate and the solid conductive plate (the bottom plate of the capacitor). In any case, other embodiments of the disclosure are not limited thereto. The number of conductive layers between the upper conductive plate and the solid conductive plate (the bottom plate of the capacitor) can be determined according to design requirements.

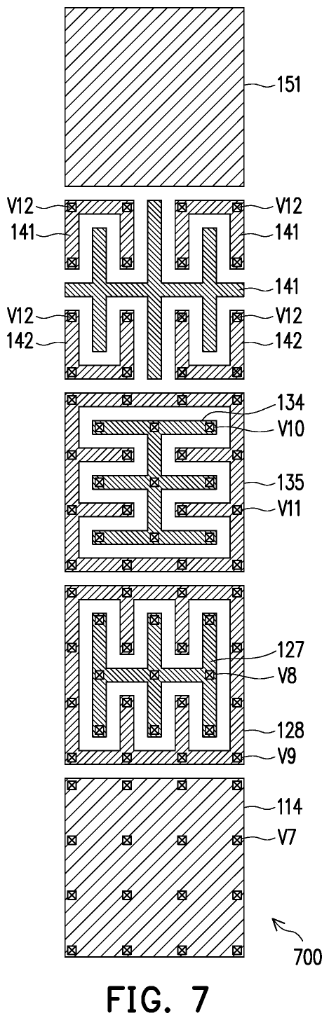

For example, FIG. 7 is a schematic top view showing a layout structure of a capacitor 700 according to yet another embodiment of the disclosure. The capacitor 700 includes a solid conductive plate 114, a first electrode 127, a second electrode 128, a third electrode 134, a fourth electrode 135, a fifth electrode 141, a sixth electrode 142, and an upper conductive plate 151. For the capacitor 700, the solid conductive plate 114, the first electrode 127, the second electrode 128, and the upper conductive plate 151 shown in FIG. 7, related description may be derived from description of the capacitor 100, the solid conductive plate 111, the first electrode 121, the second electrode 122 and the upper conductive plate 131 shown in FIG. 1 and FIG. 2, and (or) from related description of the capacitor 300, the solid conductive plate 112, the first electrode 123, the second electrode 124, and the upper conductive plate 132 shown in FIG. 3 and FIG. 4, and (or) from related description of the capacitor 500, the solid conductive plate 113, the first electrode 125, the second electrode 126, and the upper conductive plate 133 shown in FIG. 5 and FIG. 6.

In the embodiment shown in FIG. 7, the solid conductive plate 114 is disposed at the first conductive layer of the wafer, and the first electrode 127 and the second electrode 128 are located at the second conductive layer of the wafer. The second electrode 128 may be electrically connected to the solid conductive plate 114 through a plurality of via plugs V7. The second electrode 128 may encircle the first electrode 127 to reduce the parasitic capacitor between the top plate (first electrode 127) of the capacitor 700 and the substrate (not shown) of the wafer.

The third electrode 134 and the fourth electrode 135 are disposed at the third conductive layer of the wafer. The third electrode 134 and the fourth electrode 135 are arranged above the first electrode 127 and the second electrode 128, so that the first electrode 127 and the second electrode 128 are located between the solid conductive plate 114 and the third electrode 134, and that the first electrode 127 and the second electrode 128 are located between the solid conductive plate 114 and the fourth electrode 135. The third electrode 134 may be electrically connected to the first electrode 127 through a plurality of via plugs V8. The fourth electrode 135 may be electrically connected to the second electrode 128 through a plurality of via plugs V9. Therefore, the fourth electrode 135 can be electrically connected to the solid conductive plate 114. The fourth electrode 135 is arranged beside the third electrode 134. The fourth electrode 135 may encircle the third electrode 134 to reduce the parasitic capacitor between the top plate (third electrode 134) of the capacitor 700 and the substrate (not shown) of the wafer.

The fifth electrode 141 and the sixth electrode 142 are disposed at the fourth conductive layer of the wafer, and the upper conductive plate 151 is disposed at the fifth conductive layer of the wafer. The fifth electrode 141 may be electrically connected to the third electrode 134 through a plurality of via plugs V10. The sixth electrode 142 may be electrically connected to the fourth electrode 135 through a plurality of via plugs V11. The sixth electrode 142 may encircle the fifth electrode 141. The upper conductive plate 151 may be electrically connected to the sixth electrode 142 through a plurality of via plugs V12. Therefore, the upper conductive plate 151 and the sixth electrode 142 can reduce the parasitic capacitor between the top plate (fifth electrode 141) of the capacitor 700 and the substrate (not shown) of the wafer.

In summary, the capacitor described in the above embodiments can use the bottom plate (solid conductive plate) as a shielding layer. The solid conductive plate can effectively reduce the parasitic capacitor between the top plate of the capacitor and the substrate of the wafer.

Although the present disclosure has been disclosed in the above embodiments, it is not intended to limit the present disclosure, and those skilled in the art can make some modifications and refinements without departing from the spirit and scope of the disclosure. Therefore, the scope of the present disclosure is subject to the definition of the scope of the appended claims.

What is claimed is:

1. A capacitor, comprising:
a solid conductive plate arranged above a substrate of a wafer, wherein the solid conductive plate serves as a bottom plate of the capacitor;
a first electrode disposed above the solid conductive plate so that the solid conductive plate is located between the substrate and the first electrode, wherein the first electrode serves as a top plate of the capacitor; and
a second electrode arranged above the solid conductive plate and beside the first electrode, wherein the second electrode is electrically connected to the solid conductive plate.

2. The capacitor according to claim 1, wherein the first electrode and the second electrode are located at the same conductive layer.

3. The capacitor according to claim 1, wherein the second electrode encircles the first electrode.

4. The capacitor according to claim 1, wherein an interdigitated finger structure is provided between the first electrode and the second electrode.

5. The capacitor according to claim 1, further comprising:
an upper conductive plate disposed above the first electrode and the second electrode so that the first electrode and the second electrode are located between the upper conductive plate and the solid conductive plate, wherein the upper conductive plate is electrically connected to the solid conductive plate.

6. The capacitor according to claim 5, wherein the upper conductive plate is another solid conductive plate.

7. The capacitor according to claim 5, wherein a central portion of the upper conductive plate has at least one opening.

8. The capacitor according to claim 7, wherein a width of the opening is less than or equal to half of a width of the upper conductive plate.

9. The capacitor according to claim 1, further comprising:
a third electrode disposed above the first electrode and the second electrode so that the first electrode and the second electrode are located between the solid conductive plate and the third electrode, wherein the third electrode is electrically connected to the first electrode; and
a fourth electrode disposed above the first electrode and the second electrode, and is arranged beside the third electrode, wherein the fourth electrode is electrically connected to the solid conductive plate.

10. The capacitor according to claim 9, wherein the solid conductive plate is disposed at a first conductive layer, the first electrode and the second electrode are disposed at a second conductive layer, and the third electrode and the fourth electrode are disposed at a third conductive layer.
